(19) United States
(12) Patent Application Publication
(10) Pub. No.: US 2015/0098161 A1
(43) Pub. Date: Apr. 9, 2015

(54) INTEGRATED CORONA FAULT DETECTION

(71) Applicant: Hamilton Sundstrand Corporation, Windsor Locks, CT (US)

(72) Inventors: John Horowy, Rockford, IL (US); Gary L. Galloway, Rockford, IL (US); Waleed M. Said, Rockford, IL (US); Debabrata Pal, Hoffman Estates, IL (US)

(73) Assignee: Hamilton Sundstrand Corporation, Windsor Locks, CT (US)

(21) Appl. No.: 14/189,329

(22) Filed: Feb. 25, 2014

Related U.S. Application Data
(60) Provisional application No. 61/888,897, filed on Oct. 9, 2013.

(51) Int. Cl. G01R 27/16; G01J 1/44; H02H 9/02

(52) U.S. Cl. CPC G01R 27/16; H02H 9/02; G01J 1/44
USPC 361/87; 324/658

(57) ABSTRACT

A power distribution cabinet includes a housing having walls that define an interior space for housing electric components. A capacitive sensor is located on an interior surface of one or more of the walls. The capacitive sensor includes a first conductive layer located proximate to the interior surface of the wall, a second conductive layer located distal from the interior surface of the wall, and a dielectric layer located between the first and second conductive layers. First and second output terminals are connected to the first and second conductive layers of the capacitive sensor to provide an output representative of displacement current within the power distribution cabinet.

### CROSS-REFERENCE TO RELATED APPLICATION

This application claims priority to U.S. Provisional Application No. 61/888,897, filed on Oct. 10, 2013, and entitled “Integrated Corona Fault Detection,” the disclosure of which is incorporated by reference in its entirety.

### BACKGROUND

The present invention relates to fault protection and in particular to detection of corona events. Electrical boxes are used in a variety of applications to enclose electrical components. In some cases, voltages associated with the electrical components within a box may generate a corona event. Corona events are a well-known phenomenon in which ions form in a fluid (such as air) between two components of different voltages. In a corona event, the electric field around an object is high enough to form a conductive region, but not high enough to cause electrical breakdown or arcing to nearby objects.

If unchecked, the electric field may eventually result in electrical breakdown (i.e., an arc fault) arcing. Such arcing can be destructive to electronic components. In the context of an electrical box, arcing presents hazards including damage to the arcing component, damage to adjacent components, and fire hazard.

### SUMMARY

A power distribution cabinet includes a housing having walls that define an interior space for housing electric components. A capacitive sensor is located on an interior surface of one or more of the walls. The capacitive sensor includes a first conductive layer located proximate to the interior surface of the wall, a second conductive layer located distal from the interior surface of the wall, and a dielectric layer located between the first and second conductive layers. First and second output terminals are connected to the first and second conductive layers of the capacitive sensor to provide an output representative of displacement current within the power distribution cabinet.

### BRIEF DESCRIPTION OF THE DRAWINGS

FIG. 1 is a cross-sectional plan view of a fault detection system employed in an electrical box.

FIG. 2 is a flowchart illustrating operation of the fault detection system.

### DETAILED DESCRIPTION

A corona detection system is described that allows for the detection of corona events within an electrical box. Capacitive sensors are located along interior walls of the electrical box, and provide an output indicative of displacement current in a region adjacent to the sensor that can be used to detect corona events. Remedial actions can then be taken in response to the detected corona event to prevent more serious arc fault events. Maximum functionality of the electronic components housed in the box is maintained by a controller that is capable of determining which zone the corona event (or arcing) occurred in, and maintaining power to electronic components in other zones while powering down potentially hazardous components.

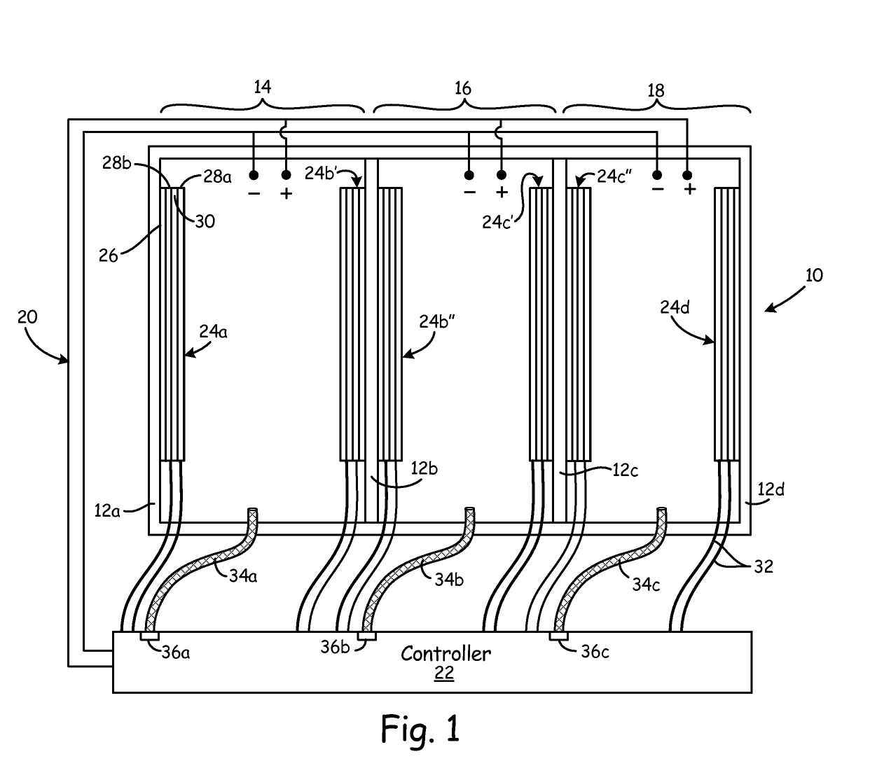

FIG. 1 is a cross-sectional plan view of electrical box 10 having three distinct zones. In the embodiment shown in FIG. 1, box 10 is a power distribution cabinet that includes walls 12 that divide box 10 into first zone 14, second zone 16, and third zone 18. Each of the zones 14, 16, and 18 include power components that are supplied with power via power supply bus 20. Controller 22 controls the allocation and distribution of power from power supply bus 20 to each of the zones 14, 16, and 18. Within each of the zones are capacitive sensors 24. In the embodiment shown in FIG. 1, first zone 14 contains capacitive sensor 24a arranged on wall 12a, as well as capacitive sensor 24b′ arranged on wall 12b. Second zone 16 contains capacitive sensor 24b″ arranged on wall 12b, as well as capacitive sensor 24c′ arranged on wall 12c. Third zone 18 contains capacitive sensor 24c″ arranged on wall 12c, as well as capacitive sensor 24d arranged on wall 12d. Each of capacitive sensors 24 includes pad 26, a first layer of conductive material 28a, dielectric material 30, and a second layer of conductive material 28b. Leads 32 are attached to each of the conductive material layers 28a and 28b of capacitive sensors 24.

Capacitive sensors 24 are arranged on walls 12. Each of capacitive sensors 24 is configured to detect a corona buildup in an adjacent zone. Capacitive sensors 24 detect displacement currents within adjacent zones. Detection of displacement currents are used to detect corona build-up in the zone adjacent to the capacitive sensor. Capacitive sensors 24 may cover a significant portion of walls 12. For example, in one embodiment, capacitive sensors 24 cover a majority of the surface area of walls 12 adjacent to each zone. Capacitive sensors 24 may be arranged on any of the walls of box 10. In alternative embodiments, more than one capacitive sensor 24 may be arranged on each of walls 12.

Corona events cause electrical current (i.e., displacement current) to flow between the plates formed by conductive materials 28a and 28b. The geometry and location of capacitive sensors 24 allows capacitive sensors 24 to detect displacement currents in zones 14, 16, and 18 adjacent to capacitive sensors 24. Corona buildup has a known frequency signature that can be measured to detect a corona buildup. Controller 22 measures the voltage across capacitive sensors 24, and based on the frequencies measured can determine when a corona buildup is occurring. In response to a detected corona event, controller 22 may undertake remedial actions, such as reducing power distribution to electrical components of the affected zone 12.

In addition to corona events, which are precursors to an arc event, controller 22 also monitors for arc fault events. For example, in the embodiment shown in FIG. 1, fiber optic cables 34 are positioned to route light signals from first zone 14, second zone 16, and third zone 18, respectively, to controller 22, which includes a plurality of photodetectors 36. In the event of arcing, light is emitted which is detected by controller 22 via fiber optic cables 34. Because walls 12 separate each of the zones from one another, light caused by arcing within one zone will only be routed to controller 22 by fiber optic cable 34 attached to that particular zone. For example, in the event that capacitive sensors 24b″ and 24e indicate a corona event in second zone 16, controller 22 may reduce power distributed to second zone 16 via bus 20. If photodetector 36b then detects a flash of light in second zone 16 despite those initial remedial measures, controller 22 may disconnect all power to electrical components in second zone 16.

In alternative embodiments, varying numbers of capacitive sensors may be distributed in each zone (e.g., 14, 16, 18). In some embodiments, only one capacitive sensor 24 need by used, whereas in others a plurality of capacitive sensors 24 may he arranged in each zone. In alternative embodiments, the number of capacitive sensors 24 employed in each zone need not be the same. Capacitive sensors 24 can he arranged on walls 12, or other structures within box 10. Additionally, the number of zones in alternative embodiments may vary based on the needs of the electrical box. In some embodiments, a single zone may be used that contains all the electrical components of a system. Furthermore, there can be multiple photo-detectors and fiber optic cables or multiple fiber optic cables connected to single photo-detector in one zone. This will allow better detection and provide redundancy.

In one embodiment, additive manufacturing is used to build the layers of capacitive sensors 24. In one example, ultrasonic additive manufacturing is used to apply pad 26, a first layer of conductive material 28, dielectric material 30, and a second layer of conductive material 28. In this way, two capacitive plates are built up of the conductive material 28 with a dielectric material 30 in between them, electrically isolated from box 10 and walls 12 by pad 26.

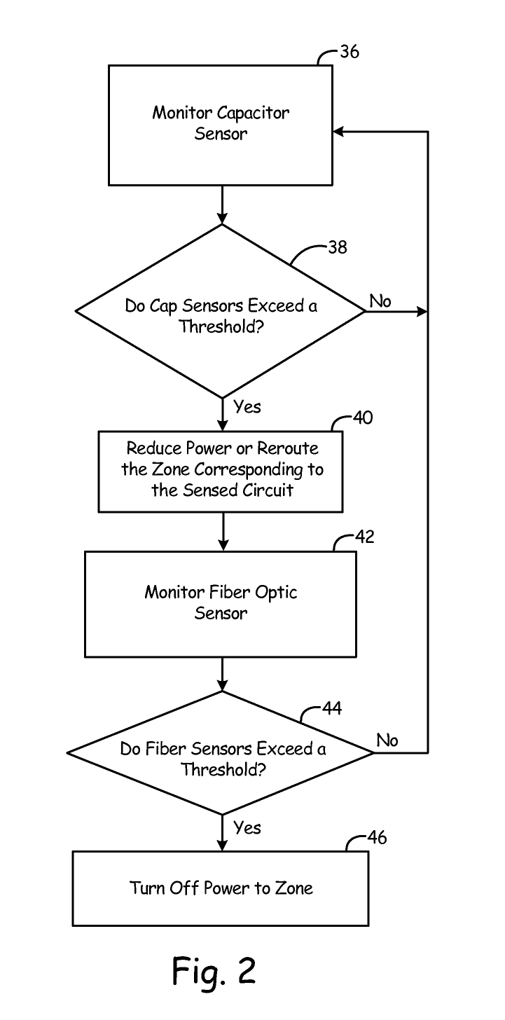

FIG. 2 is a flow chart illustrating steps performed by controller 22 in detecting and responding to corona events. Continued reference is made to elements described with respect to FIG. 1.

At step 36, controller 22 monitors capacitive sensors 24 to detect the presence of displacement currents indicative of a corona event. As previously described, displacement current can be used to identify corona events by current amplitudes and frequencies that are unique to such phenomena.

At step 38, controller 22 determines whether the current at the capacitive sensors indicate a corona event. The output of sensors 24 is measured against a reference voltage, current, and frequency, to determine whether a corona event has occurred. If the current at the capacitive sensors does not exceed the threshold in a specific frequency pattern, monitoring of the sensors continues as described with respect to step 38.

If the measured current of step 38 exceeds the threshold, then at step 40, controller 22 reduces or reroutes power to the zone in which the corona event was detected. Often, the controller is configured to measure current flow of several capacitive sensors within each of several zones. Power can be reduced to only those zones for which measured capacitor current at step 38 exceeds such a threshold.

At step 42, controller 22 receives optical data from a photodetector 36 attached to a fiber optic cable. Optical data may be provided contemporaneously with monitored capacitive data, or may be monitored only in response to a detected corona event. In the event of arcing, light can be routed from the affected zone via fiber optic cable 34 to photodetector 36.

At step 44, data received from photodetector 36 is analyzed to determine whether the optical signal is greater than a threshold. If, after power reduction at step 40, the optical sensor data does not exceed the threshold, then an arc has likely not occurred. In that event, capacitor sensor current may continue to be monitored at step 36.

At step 46, if the optical signal is greater than a threshold, an arc has likely occurred and the affected zone is disconnected from power. As with corona/capacitive current, the controller can turn off power to only a zone in which the optical data exceeded a threshold.

In an alternative embodiment, the photodetection and capacitive sensing may be used in parallel, rather than sequentially. For example, if the capacitor detection fails, the photo detection will still work, thus providing a more redundant detection system.

### Discussion of Possible Embodiments

The following are non-exclusive descriptions of possible embodiments of the present invention.

A power distribution cabinet includes a housing having walls that define an interior space for housing electric components. The power distribution cabinet further includes a capacitive sensor located on an interior surface of one or more of the walls. The capacitive sensor includes a first conductive layer located proximate to the interior surface of the wall, a second conductive layer located distal from the interior surface of the wall, and a dielectric layer located between the first and second conductive layers. The power distribution cabinet also includes first and second output terminals connected to the first and second conductive layers of the capacitive sensor to provide an output representative of displacement current within the power distribution cabinet.

The power distribution cabinet of the preceding paragraph can optionally include, additionally and/or alternatively, any one or more of the following features, configurations and/or additional components:

The power distribution cabinet may have a plurality of zones defined by a plurality of walls, each zone having at least one capacitive sensor located on an interior surface of the zones. First and second output terminals may be associated with each capacitive sensor. At least two capacitive sensors may be arranged within each of the plurality of zones. The power distribution cabinet may also include a photodetector configured to receive optical data indicative of an electrical discharge. The power distribution cabinet may also include a third output connectable to the photodetector to provide an output representative of the electrical discharge. The power distribution cabinet may also include a controller configured to receive the output provided via the first and second output terminals, and to selectively control power supplied to the electric components housed within the plurality of zones. The controller may reduce power to the electric components within one of the plurality of zones in the event that displacement current sensed by one of the capacitive sensors associated with the particular zone exceeds a threshold. The capacitive sensor may include a stack of layers that are welded together ultrasonically. The power distribution cabinet may also include a fiber optic cable that couples the zone and the photodetector. The power distribution cabinet may also include a wall positioned at the perimeter of the zone to define the interior surface.

According to a further embodiment of the present invention, a method of preventing electrical discharge includes sensing a charge buildup in a capacitor located in a zone, wherein the charge buildup is indicative of a corona. The method includes modifying power output to an electrical component located in the zone.

The method of the preceding paragraph can optionally include, additionally and/or alternatively, any one or more of the following features, steps, configurations and/or additional components:

The method may further include sensing optical data at a photodetector, wherein the optical data is indicative of an electrical discharge, and turning off power to the electrical component. Modifying power output to the electrical component may include reducing power distributed to the electrical component. Sensing the charge buildup in the capacitor may include comparing a frequency signature of a corona event to the charge buildup in the capacitor. The method may also include a plurality of zones, a plurality of capacitors, at least one capacitor arranged in each of the plurality of zones, and a controller coupled to the plurality of capacitors, the controller configured to receive data corresponding to a charge buildup in any of the plurality of capacitors. The method may also include determining which of the plurality of zones includes corona buildup based on the charge buildup in the plurality of capacitors.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

1. A power distribution cabinet comprising:
a housing having walls that define an interior space for housing electric components;
a capacitive sensor located on an interior surface of one or more of the walls, the capacitive sensor including a first conductive layer located proximate to the interior surface of the wall, a second conductive layer located distal from the interior surface of the wall, and a dielectric layer located between the first and second conductive layers; and
first and second output terminals connected to the first and second conductive layers of the capacitive sensor to provide an output representative of displacement current within the power distribution cabinet.

2. The power distribution cabinet of claim 1 and further comprising:
a plurality of zones defined by a plurality of walls, each zone having at least one capacitive sensor located on an interior surface of the zones; and
first and second output terminals associated with each capacitive sensor.

3. The power distribution cabinet of claim 2, wherein at least two capacitive sensors are arranged within each of the plurality of zones.

4. The power distribution cabinet of claim 1, and further comprising:
a photodetector configured to receive optical data indicative of an electrical discharge; and
a third output connectable to the photodetector to provide an output representative of the electrical discharge.

5. The power distribution cabinet of claim 4, and further comprising a controller configured to receive the output provided via the first and second output terminals, and to selectively control power supplied to the electric components housed within the plurality of zones.

6. The power distribution cabinet of claim 5, wherein the controller reduces power to the electric components within one of the plurality of zones in the event that displacement current sensed by one of the capacitive sensors associated with the particular zone exceeds a threshold.

7. The power distribution cabinet of claim 1, wherein the capacitive sensor comprises a stack of layers that are welded together ultrasonically.

8. The power distribution cabinet of claim 2, and further comprising a fiber optic cable that couples the zone and the photodetector.

9. The power distribution cabinet of claim 2, and further comprising a wall positioned at the perimeter of the zone to define the interior surface.

10. A method of preventing electrical discharge, the method comprising:
sensing a charge buildup in a capacitor located in a zone, wherein the charge buildup is indicative of a corona; and
modifying power output to an electrical component located in the zone.

11. The method of claim 10, and further comprising:
sensing optical data at a photodetector, wherein the optical data is indicative of an electrical discharge; and
turning off power to the electrical component.

12. The method of claim 10, wherein modifying power output to the electrical component comprises reducing power distributed to the electrical component.

13. The method of claim 10, wherein sensing the charge buildup in the capacitor comprises comparing a frequency signature of a corona event to the charge buildup in the capacitor.

14. The method of claim 10, and further comprising:
a plurality of zones;
a plurality of capacitors, at least one capacitor arranged in each of the plurality of zones; and
a controller coupled to the plurality of capacitors, the controller configured to receive data corresponding to a charge buildup in any of the plurality of capacitors.

15. The method of claim 14, and further comprising determining which of the plurality of zones includes corona buildup based on the charge buildup in the plurality of capacitors.
